(19) United States
(12) Patent Application Publication
(10) Pub. No.: US 2020/0040445 A1
(43) Pub. Date: Feb. 6, 2020

(54) VACUUM SYSTEM AND METHOD FOR DEPOSITING A PLURALITY OF MATERIALS ON A SUBSTRATE

(71) Applicant: Applied Materials, Inc., Santa Clara, CA (US)

(72) Inventor: Oliver HEIMEL, Wabern (DE)

(21) Appl. No.: 15/744,646

(22) PCT Filed: Apr. 28, 2017
(86) PCT No.: PCT/EP2017/060242

§ 371 Date: Jan. 12, 2018

(51) Int. Cl. C23C 14/56; C23C 14/04; C23C 14/12; H01L 51/56; H01L 51/00; C23C 14/50; C23C 14/24

(52) U.S. Cl. CPC C23C 14/568; C23C 14/042; C23C 14/12; C23C 14/243; H01L 51/0011; C23C 14/50; H01L 51/56

(57) ABSTRACT

A vacuum system for depositing a plurality of materials on a substrate is described. The vacuum system includes a plurality of deposition modules arranged along a main transport direction and including deposition sources which are movable in the main transport direction; and a transport system with a plurality of tracks extending in the main transport direction through the plurality of deposition modules and including a first mask track for mask transport, a first substrate track for substrate transport and a return track for returning empty carriers.

### TECHNICAL FIELD

Embodiments of the present disclosure relate to a vacuum system for depositing a plurality of materials on a substrate. More specifically, a vacuum system for depositing one or more organic materials on substrates in a plurality of deposition modules by evaporation is described. Embodiments particularly relate to in-line vacuum deposition systems with a plurality of deposition modules arranged along a main transport direction. Embodiments further relate to methods for depositing a plurality of materials on a substrate, particularly by evaporation.

### BACKGROUND

Opto-electronic devices that make use of organic materials are becoming increasingly popular for a number of reasons. Many of the materials used to make such devices are relatively inexpensive, so organic opto-electronic devices have the potential for cost advantages over inorganic devices. The inherent properties of organic materials, such as their flexibility, may be advantageous for applications such as for the deposition on flexible or inflexible substrates. Examples of organic opto-electronic devices include organic light emitting devices, organic phototransistors, organic photovoltaic cells, and organic photodetectors.

The organic materials of OLED devices may have performance advantages over conventional materials. For example, the wavelength at which an organic emissive layer emits light may be readily tuned with appropriate dopants. OLED devices make use of thin organic films that emit light when a voltage is applied across the device. OLED devices are becoming an increasingly interesting technology for use in applications such as flat panel displays, illumination, and backlighting.

Materials, particularly organic materials, are typically deposited on a substrate in a vacuum system under sub-atmospheric pressure. During deposition, a mask device may be arranged in front of the substrate. The mask device may have a plurality of openings that define an opening pattern corresponding to a material pattern to be deposited on the substrate, e.g. by evaporation. The substrate is typically arranged behind the mask device during the deposition and is aligned relative to the mask device. For example, a mask carrier carrying the mask device may be arranged in a deposition module of the vacuum system, and a substrate carrier carrying the substrate may be transported into the deposition module for arranging the substrate behind the mask device.

Typically, two, three or more materials are subsequently deposited on a substrate, e.g. for manufacturing pixels of a color display. It may be challenging to handle a vacuum system with a plurality of deposition modules for depositing different materials on a plurality of substrates. In particular, such vacuum systems tend to be very complex, expensive and occupy a lot of space.

Accordingly, it would be beneficial to provide a compact and space-saving vacuum system configured to reliably deposit a plurality of materials on a substrate. In particular, simplifying and accelerating the substrate transport and/or the mask transport and exchange in a vacuum system configured for the deposition of materials on substrates would be beneficial.

### SUMMARY

In light of the above, vacuum systems for depositing a plurality of materials on a substrate, and methods for depositing a plurality of materials on a substrate are described.

According to one aspect of the present disclosure, a vacuum system for depositing a plurality of materials on a substrate is provided. The vacuum system includes a plurality of deposition modules arranged along a main transport direction and comprising deposition sources which are movable in the main transport direction, and a transport system with a plurality of tracks extending in the main transport direction through the plurality of deposition modules and comprising a first mask track for mask transport, a first substrate track for substrate transport and a return track for returning empty carriers.

In particular, the plurality of deposition modules may be arranged next to each other in a linear arrangement or row arrangement such that the plurality of deposition modules provide the main transportation path of the vacuum system and the deposition areas of the vacuum system. The vacuum system may be configured as an in-line vacuum deposition system.

According to an aspect of the present disclosure, a vacuum system for depositing a plurality of materials on a substrate held by a substrate carrier is provided. The vacuum system includes a first substrate handling module configured to attach a substrate to a substrate carrier, a second substrate handling module configured to detach the substrate from the substrate carrier, and a plurality of deposition modules arranged along a main transport direction between the first substrate handling module and the second substrate handling module and comprising deposition sources which are movable in the main transport direction. The vacuum system further includes at least one return track extending through the plurality of deposition modules from the second substrate handling module to the first substrate handling module. The vacuum system may be configured as an in-line vacuum deposition system.

According to an aspect of the present disclosure, a method for depositing a plurality of materials on a substrate is provided. The method includes transporting a substrate carrier holding a substrate along a first substrate track in a main transport direction through a plurality of deposition modules, depositing a plurality of materials on the substrate in the plurality of deposition modules with deposition sources which are movable in the main transport direction, and transporting an empty carrier along a return track through the plurality of deposition modules in a return direction opposite to the main transport direction.

Further aspects, advantages and features of the present disclosure are apparent from the description and the accompanying drawings.

### BRIEF DESCRIPTION OF THE DRAWINGS

So that the manner in which the above recited features of the present disclosure can be understood in detail, a more particular description of the present disclosure, briefly summarized above, may be had by reference to embodiments. The accompanying drawings relate to embodiments of the disclosure and are described in the following. Typical embodiments are depicted in the drawings and are detailed in the description which follows.

FIG. 1 is a schematic view of a vacuum system according to embodiments described herein;

FIG. 2 is a schematic view of a vacuum system according to embodiments described herein;

FIGS. 3A to 3D are schematic views illustrating various positions of a deposition source in a deposition module of a vacuum system according to embodiments described herein; and

FIG. 4 is a schematic view of a vacuum system according to embodiments described herein.

### DETAILED DESCRIPTION OF EMBODIMENTS

Reference will now be made in detail to the various embodiments, one or more examples of which are illustrated in the figures. Each example is provided by way of explanation and is not meant as a limitation. For example, features illustrated or described as part of one embodiment can be used on or in conjunction with any other embodiment to yield yet a further embodiment. It is intended that the present disclosure includes such modifications and variations.

Within the following description of the drawings, same reference numbers refer to the same or to similar components. Generally, only the differences with respect to the individual embodiments are described. Unless specified otherwise, the description of a part or aspect in one embodiment applies to a corresponding part or aspect in another embodiment as well.

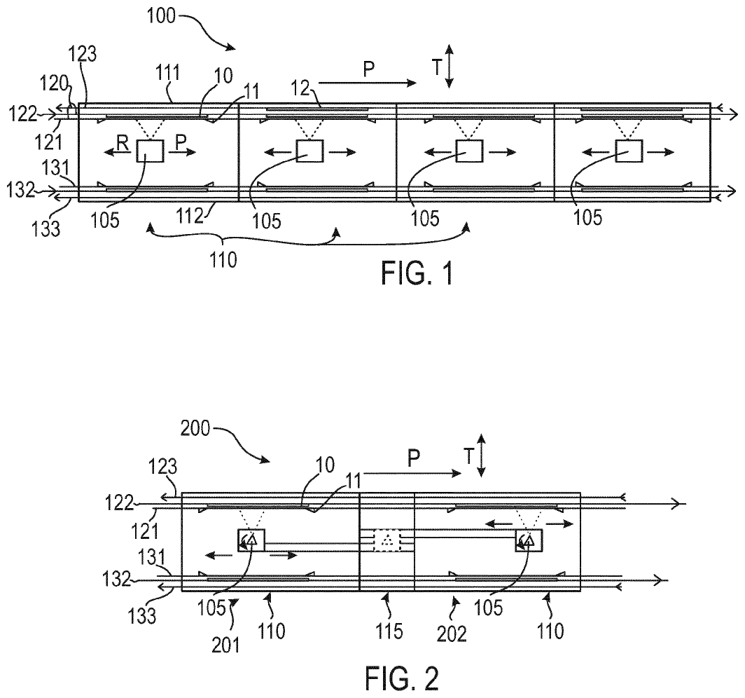

FIG. 1 is a schematic view of a vacuum system 100 for depositing a plurality of materials on a substrate 10 according to embodiments described herein. The vacuum system 100 includes a plurality of deposition modules 110 arranged along a main transport direction P and housing deposition sources 105. The deposition sources may be evaporation sources configured to direct evaporated material toward the substrate 10.

The plurality of deposition modules 110 may be arranged one after the other in a linear arrangement or line setup. Four deposition modules placed one after the other are depicted in the exemplary embodiment of FIG. 1. An in-line vacuum system may be provided. The plurality of deposition modules 110 may be arranged along a main transportation path, and the substrate 10 may be transported along the main transportation path in the main transport direction P from one deposition module to the respective subsequent deposition module. Two, three or more deposition modules may be arranged along the main transportation path. In some embodiments four, eight, twelve or more deposition modules are arranged along the main transportation path.

The substrate 10 may be transported into a first deposition module of the plurality of deposition modules 110 where a first material may be deposited on the substrate 10. Thereafter, the substrate may be transported in the main transport direction P from the first deposition module into a second deposition module of the plurality of deposition modules 110 where a second material may be deposited on the substrate. Thereafter, the substrate may be transported in the main transport direction P from the second deposition module into a third deposition modules of the plurality of deposition modules where a further material may be deposited on the substrate. Further materials may be deposited on the substrate 10 in subsequent deposition modules arranged along the main transportation path. A plurality of materials may be deposited on the substrate 10 to form a stack of layers on a main surface of the substrate.

A “deposition module” as used herein may be understood as a section or chamber of the vacuum system 100 where a material can be deposited on one or more substrates, e.g. by evaporation. Each deposition module of the plurality of deposition modules 110 houses at least one deposition source, e.g. an evaporation source configured for directing evaporated material toward one or more substrates. The deposition source 105 may be movable back and forth in the deposition module 110, in the main transport direction P and in a return direction R, e.g. along a source track which may be provided in the deposition module. Each deposition source may be movable in an associated deposition module.

The deposition sources 105 may linearly move along source tracks in the plurality of deposition modules 110 while directing evaporated material toward substrates which are arranged in the plurality of deposition modules. During deposition, mask devices may be arranged in front of the substrates. Thus, the deposition modules may be configured for the masked deposition of a material on a plurality of substrates.

The deposition sources 105 in at least some of the deposition modules 110 may move in phase. In other words, the deposition sources 105 may move together in the main transport direction P, change direction essentially synchronously, and move together in a return direction R opposite to the main transport direction. A plurality of substrates may be coated essentially synchronously in the plurality of deposition modules. After the deposition of a material layer, the plurality of substrates may be transported essentially synchronously in the main transport direction P into the respective subsequent deposition module where a further material layer may be deposited on the plurality of substrates.

The vacuum system 100 may be configured as an in-line deposition system. An “in-line deposition system” as used herein may be understood as a deposition system including a plurality of deposition modules arranged along a main transportation path along which the substrates are transported. The substrate 10 may be stopped at predetermined positions along the main transportation path in respective deposition modules where a material is deposited on the substrate. During deposition, the substrate 10 may be held essentially stationary, particularly in alignment with a mask device, and a deposition source may move past the stationary substrate while directing evaporated material toward the substrate 10.

In some embodiments, which may be combined with other embodiments described herein, a deposition module may include two deposition areas arranged on opposite sides of the deposition source, i.e. a first deposition area for arranging a first substrate and a second deposition area for arranging a second substrate. The deposition source may be configured to subsequently direct evaporated material toward the first substrate arranged in the first deposition area and toward the second substrate arranged in the second deposition area. For example, an evaporation direction of the deposition source may be reversible, e.g. by rotating at least a part of the deposition source, e.g. by an angle of 180°.

During the deposition on a first substrate arranged in the first deposition area of a deposition module, the second deposition area may be used for at least one or more of: moving a second substrate to be coated into the second deposition area; moving a coated second substrate out of the second deposition area; aligning a second substrate in the second deposition area, e.g. with respect to a mask device provided in the second deposition area. Similarly, during the deposition on a second substrate arranged in the second deposition area of a deposition module, the first deposition area may be used for at least one or more of: moving a first substrate to be coated into the first deposition area, moving a coated first substrate out of the first deposition area, and aligning a first substrate in the first deposition area, e.g. with respect to a mask device provided in the first deposition area. Accordingly, by providing two deposition areas in a deposition module, the number of coated substrates in a given time interval can be increased. Further, idle times of the deposition source can be reduced.

According to embodiments described herein, the vacuum system 100 includes a transport system with a plurality of tracks 120 extending in the main transport direction P through the plurality of deposition modules 110 and including a first mask track 121 for mask transport, a first substrate track 122 for substrate transport and a return track 123 for returning empty carriers.

The first substrate track 122 may be configured for the transport of a substrate carrier along the first substrate track 122, wherein the substrate carrier carries a substrate. In particular, a substrate carrier which holds a substrate can be transported along the first substrate track 122 in the main transport direction P through the plurality of deposition modules 110, e.g. from a first deposition module where a first material is deposited on the substrate to a second deposition module where a second material is deposited on the substrate.

The first mask track 121 may be configured for the transport of a mask carrier which holds a mask device along the first mask track 121. In particular, a mask carrier which holds a mask device can be transported along the first mask track 121 in the main transport direction P, e.g. from a first deposition module into a second deposition module and/or vice versa.

The first mask track 121 may be provided in an area between the deposition sources 105 and the first substrate track 122 such that a mask device can be arranged on the first mask track in front of a substrate. Accordingly, evaporated material may be directed from the deposition source 105 through the mask device toward the substrate which is arranged on the first substrate track 122.

The return track 123 may be configured for the transport of empty carriers in a reverse direction R, i.e. in a direction opposite to the main transport direction P. For example, the return track 123 may be configured for returning empty substrate carriers toward an upstream section of the vacuum system where a new substrate to be coated may be attached to the substrate carrier. An empty carrier 12 is schematically depicted in FIG. 1 on the return track 123. An empty carrier as used herein may be understand as an unoccupied substrate carrier or mask carrier which does not carry a substrate or mask.

In some embodiments, the first substrate track 122 may be arranged between the first mask track 121 and the return track 123. In other words, the return track 123 may be provided “behind” the first substrate track 122 from the perspective of the deposition source 105. Therefore, empty carriers can be transported in the return direction R toward an upstream section of the vacuum system without interfering with the deposition process. The return track 123 may extend through the plurality of deposition modules 110 from a downstream section of the vacuum system to an upstream section of the vacuum system. When the return track for the empty carriers is provided in the deposition modules, no additional vacuum chambers for providing a return track for the transport of empty carriers may be needed.

According to embodiments described herein, the plurality of deposition modules 110 can be utilized as the main transportation path for the substrates, as the main transportation path for the mask devices, as the return path for the empty carriers, and as the deposition areas for depositing materials on the substrates. Accordingly, space and costs can be saved and a compact vacuum system can be provided. In particular, a free space behind the first substrate track within the deposition modules can be utilized for returning empty carriers into an upstream section of the vacuum system.

In some embodiments, the first mask track 121, the first substrate track 122, and the return track 123 may extend parallel to each other on a first side of the deposition sources 105. For example, a distance between the first substrate track 122 and the first mask track 121 may be 10 cm or less, and/or a distance between the return track 123 and the first substrate track 122 may be 20 cm or less, particularly 10 cm or less. The first mask track 121 may be arranged closest to the deposition sources 105, and the return track 123 may be arranged farthest from the deposition sources 105. Arranging the first mask track 121 essentially parallel to the first substrate track 122 may have the advantage that mask carriers holding mask devices and substrate carriers holding substrates can be transported essentially parallel to each other along the plurality of tracks 120 through subsequent deposition modules. Further, a substrate on the first substrate track may be held essentially parallel to a mask device on the first mask track during deposition.

At predetermined positions within the deposition modules, the substrate carriers may stop, may be aligned with respect to the mask carriers arranged in front of the substrate carriers, and a material may be deposited on the substrates through the mask device.

In some embodiments, the return track 123 may be arranged between the first substrate track 122 and a first side wall 111 of the plurality of deposition modules 110. For example, the return track 123 may be arranged at a close distance from and/or essentially parallel to the first side wall 111 of the plurality of deposition modules 110, e.g. at a distance of 30 cm or less, particularly 20 cm or less, more particularly 15 cm or less from the first side wall 111. A small distance between the return track 123 and the first side wall 111 may have the advantage that the transport of empty carriers along the return track 123 may not negatively affect the deposition on the substrates on the first substrate track 122.

In some embodiments, which may be combined with other embodiments described herein, the plurality of tracks 120 further includes a second mask track 131 for mask transport and a second substrate track 132 for substrate transport, and optionally a second return track 133 for returning empty carriers.

The second mask track 131 and the second substrate track 132 may extend parallel to each other on a second side of the deposition sources 105 opposite to the first side. In other words, the first mask track 121 and the first substrate track 122 may be arranged on the first side of the deposition sources 105, and the second mask track 131 and the second substrate track 132 may be arranged on the second side of the deposition sources opposite to the first side.

In some embodiments, the deposition sources 105 may be rotatable. In a first rotation position, the deposition sources 105 may be directed toward the first substrate track 122 for depositing an evaporated material on a substrate on the first substrate track, and, in a second rotation position, the deposition sources 105 may be directed toward the second substrate track 132 for depositing an evaporated material on a substrate on the second substrate track. By rotating the deposition sources, e.g. by an angle of about 180°, the deposition sources 105 may direct evaporated material into two opposite directions, i.e. toward the first deposition area where the first substrate track 122 is arranged and toward the second deposition area where the second substrate track 132 is arranged.

In some embodiments, a second return track 133 may be provided on the second side of the deposition sources 105, particularly between the second substrate track 132 and a second side wall 112 of the plurality of deposition modules. The second side wall 112 and the first side wall 111 may be opposite side walls of the deposition modules and may extend parallel to the main transport direction P.

The second mask track 131 may be configured for the transport of a mask carrier along the second mask track 131. In particular, a mask carrier which holds a mask device can be transported along the second mask track 131 in the main transport direction P, e.g. from a first deposition module into a second deposition module or vice versa.

The second mask track 131 may be located in an area between the deposition sources 105 and the second substrate track 132 such that a mask device can be arranged on the second mask track in front of a substrate. Accordingly, evaporated material may be directed from the deposition source 105 through a mask device arranged on the second mask track toward the substrate arranged on the second substrate track 132.

The second return track 133 may be configured for the transport of empty carriers in the reverse direction R. For example, the second return track 133 may be configured for returning empty substrate carriers toward an upstream section of the vacuum system where a new substrate to be coated may be attached to the substrate carrier.

In some embodiments, the second substrate track 132 may be provided between the second mask track 131 and the second return track 133. In other words, the second return track 133 may extend “behind” the second substrate track 132 from the perspective of the deposition source 105. Therefore, empty carriers can be transported back toward an upstream section of the vacuum system without interfering with the deposition process. The second return track 133 may extend through the plurality of deposition modules 110 from a downstream section of the vacuum system to an upstream section of the vacuum system.

In some embodiments, the second mask track 131, the second substrate track 132, and the second return track 133 may extend parallel to each other on the second side of the deposition sources 105. The second mask track 131 may be arranged closest to the deposition sources 105, and the second return track 133 may be arranged farthest from the deposition sources 105.

In some embodiments, which may be combined with other embodiments described herein, the plurality of tracks 120 is configured for transporting substrate carriers and mask carriers in an essentially vertical orientation. For example, the first substrate track 122 and/or the second substrate track 132 may be configured for transporting substrate carriers holding substrates in an essentially vertical orientation. The orientation of the substrates may be essentially vertical during the deposition of a material on the substrates and/or during the transport of the substrates through the plurality of deposition modules in the main transport direction P. The first mask track 121 and/or the second mask track 131 may be configured for transporting mask carriers holding mask devices in an essentially vertical orientation. The orientation of the mask devices may be essentially vertical during the deposition of a material on a substrate through the mask device and/or during the transport of the mask devices through the deposition modules along the mask tracks. The orientation of the empty carriers on the return track 123 and/or on the second return track 133 may be essentially vertical during the transport of the empty carriers through the plurality of deposition modules along the return track and/or along the second return track.

An “essentially vertical orientation” as used herein may be understood as an orientation with a deviation of 10° or less, particularly 5° or less from a vertical orientation, i.e. from the gravity vector. For example, an angle between a main surface of a substrate (or mask device) and the gravity vector may be between +10° and −10° during the transport through the plurality of deposition modules and/or during deposition. In some embodiments, the orientation of the substrate (or mask device) may not be exactly vertical during transport and/or during deposition, but slightly inclined with respect to the vertical axis, e.g. by an inclination angle between −1° and −5°. A negative angle refers to an orientation of the substrate (or mask device) wherein the substrate (or mask device) is inclined downward. A deviation of the substrate orientation from the gravity vector during deposition may be beneficial and might result in a more stable deposition process, or a facing down orientation might be suitable for reducing particles on the substrate during deposition. However, also an exactly vertical orientation (+/−1°) during transport and/or during deposition is possible.

In some embodiments, at least some of the deposition sources 105 may be configured as evaporation sources. The present disclosure is however not restricted to vacuum systems with evaporation sources. For example, chemical vapor deposition (CVD) systems, physical vapor deposition (PVD) systems, e.g. sputter systems, and/or evaporation systems were developed to coat substrates, e.g. thin glass substrates, e.g. for display applications, in a deposition module.

The substrate may be an inflexible substrate, e.g., a wafer, slices of transparent crystal such as sapphire or the like, a glass substrate, or a ceramic plate. However, the present disclosure is not limited thereto and the term substrate may also embrace flexible substrates such as a web or a foil, e.g. a metal foil or a plastic foil.

The substrate 10 may be a large area substrate in some embodiments. A large area substrate may have a surface area of 0.5 m² or more, particularly 1 m² or more. Specifically, a large area substrate may be used for display manufacturing and be a glass or plastic substrate. For example, substrates as described herein shall embrace substrates which are typically used for an LCD (Liquid Crystal Display), a PDP (Plasma Display Panel), and the like. For instance, a large area substrate can have a main surface with an area of 1 m² or larger. In some embodiments, a large area substrate can be GEN 4.5, which corresponds to about 0.67 m² substrates (0.73×0.92 m), GEN 5, which corresponds to about 1.4 m² substrates (1.1 m×1.3 m), or larger. A large area substrate can further be GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. The mask devices may be larger than the substrates in order to provide for a complete overlap with the substrates during deposition.

In some implementations, a thickness of the substrate in a direction perpendicular to the main surface of the substrate may be 1 mm or less, e.g. from 0.1 mm to 1 mm, particularly from 0.3 mm to 0.6 mm, e.g. 0.5 mm. Even thinner substrates are possible.

In some embodiments, a mask device 11 may include a mask and a mask frame. The mask frame may be configured to stabilize the mask which is typically a delicate component. For example, the mask frame may surround the mask in the form of a frame. The mask may be permanently fixed to the mask frame, e.g. by welding, or the mask may be releasably fixed to the mask frame. A circumferential edge of the mask may be fixed to the mask frame.

The mask may include a plurality of openings formed in a pattern and configured to deposit a corresponding material pattern on a substrate by a masked deposition process. During deposition, the mask may be arranged at a close distance in front of the substrate or in direct contact with the front surface of the substrate. For example, the mask may be a fine metal mask (FMM) with a plurality of openings, e.g. 100.000 openings or more. For example, a pattern of organic pixels may be deposited on the substrate. Other types of masks are possible, e.g. edge exclusion masks.

In some embodiments, the mask device may be at least partially made of a metal, e.g. of a metal with a small thermal expansion coefficient such as invar. The mask may include a magnetic material so that the mask can be magnetically attracted toward the substrate during deposition.

The mask device may have an area of 0.5 m² or more, particularly 1 m² or more. For example, a height of the mask device may be 0.5 m or more, particularly 1 m or more, and/or a width of the mask device may be 0.5 m or more, particularly 1 m or more. A thickness of the mask device may be 1 cm or less, wherein the mask frame may be thicker than the mask.

According to embodiments described herein, the transport system with the plurality of tracks 120 is configured for transporting mask carriers holding mask devices, substrate carriers holding substrates and empty carriers through the deposition modules. The empty carriers may be empty substrate carriers and/or empty mask carriers. In some embodiments, the transport system may be configured for a contactless transport of the substrate carriers and the mask carriers. For example, the transport system may include a plurality of active magnetic elements or magnetic levitation devices for holding substrate carriers at the substrate tracks in a contactless manner and/or for holding mask carriers at the mask tracks in a contactless manner.

In some embodiments, magnetic levitation devices may be provided for a contactless transport of substrate carriers along the first substrate track 122 and/or along the second substrate track 132. In some embodiments, magnetic levitation devices may be provided for a contactless transport of mask carriers along the first mask track 121 and/or along the second mask track 131. In some embodiments, magnetic levitation devices may be provided for a contactless transport of empty carriers, particularly empty substrate carriers, along the return track 123 and/or along the second return track 133.

In some embodiments, the magnetic levitation devices include levitation boxes with active magnet units configured to provide a magnetic force for carrying the weight of a carrier and drive boxes configured to move the levitated carrier along a track. The levitation devices may be arranged in drop-in boxes provided at a top wall of the vacuum system. For example, the magnetic levitation devices may be arranged in depressed slots provided in the top wall of the vacuum system.

In some embodiments, the substrate carriers and the mask carriers may have the same height in a vertical direction. In this case, the substrate tracks and the mask tracks may be arranged at the same height in the vacuum system. In other embodiments, the height of the mask carriers may be larger than the height of the substrate carriers. In this case, the mask tracks and the substrate tracks may be arranged at different heights.

Contactless transport systems can reduce the particle generation in the deposition modules. The deposition quality can be improved.

In some embodiments, which can be combined with other embodiments described herein, the deposition sources 105 may be rotatable around a respective rotation axis, particularly around an essentially vertical rotation axis. Alternatively or additionally, the deposition sources may be linearly movable along source tracks extending in the main transport direction P. A “rotation” of a deposition source as used herein may be understood as a change of the evaporation direction of the deposition source from a first direction to a second direction different from the first direction. For example, the evaporation direction may be reversible between a first direction and a second direction opposite to the first direction. In particular, a “rotation” of the deposition source includes all types of pivoting or swing movements of the deposition source.

In some embodiments, the deposition sources 105 may be configured for a contactless transport along the source tracks in the deposition modules. In particular, magnetic levitation devices may be provided along the main transport direction P for a contactless transport of the deposition sources along respective source tracks. Particle generation in the deposition modules can be further reduced when the deposition sources 105 are translated in a contactless manner along the source tracks.

The deposition sources 105 may be configured to deposit organic materials on the substrates. For example, a first material may be deposited on the substrate in a first deposition module by a first deposition source, a second material may be deposited on the substrate in a second deposition module by a second deposition source, and a third material may be deposited on the substrate in a third deposition module by a third deposition source. The first material may be a first color material of an array of pixels, e.g. a blue color material, and/or the second material may be a second color material of an array of pixels, e.g. a red color material. A third color material of the array of pixels, e.g. a green color material, may be deposited previously or subsequently. In particular, further materials may be deposited on the substrate prior to or subsequent to the first and second materials in the other deposition modules of the plurality of deposition modules. At least some of the materials, e.g. the first material and the second material may be organic materials. At least one material may be a metal. For example, one or more of the following metals may be deposited in some of the deposition modules: Al, Au, Ag, Cu. At least one material may be a transparent conductive oxide material, e.g. ITO. At least one material may be a transparent material.

The deposition source may be an evaporation source including a crucible and a distribution pipe extending in an essentially vertical direction and having a plurality of vapor openings. The crucible may be configured for heating and evaporating the material to be deposited. The evaporated material may be guided into the distribution pipe and through the plurality of vapor openings in the distribution pipe toward the substrate.

In some embodiments, an evaporation source may include two or more crucibles for heating and evaporating different materials, e.g. a host and a dopant. Each crucible may be in fluid communication with an associated distribution pipe having a plurality of vapor outlets for directing an evaporated material toward a substrate. For example, two or three distribution pipes may be arranged next to each other such that the plumes of evaporated material emanating from the vapor openings of the distribution pipes can be directed toward a common surface area of the substrate to be coated.

In some embodiments, which may be combined with other embodiments described herein, the vacuum system 100 may further include an alignment unit configured for aligning a substrate carrier on the first substrate track 122 with respect to a mask carrier on the first mask track 121. The alignment unit may be arranged at least partially between the first mask track 121 and the first substrate track 122 such that the alignment unit can move the substrate carrier with respect to the mask carrier into a correct relative position.

The alignment unit may be connected to a stationary part such as a wall of a deposition module, and may have a first mount for mounting a substrate carrier to the alignment unit and a second mount for mounting a mask carrier to the alignment unit. For example, the alignment unit may have a first magnetic mount for gripping the substrate carrier and a second magnetic mount for gripping the mask carrier. An actuator may be arranged between the first mount and the second mount such that the first mount and the second mount can be moved relative to each other, e.g. depending on the signal of a position sensor. In some embodiments, the actuator of the alignment unit may be a piezoelectric actuator. The actuator may be configured for moving the first mount relative to the second mount in at least two dimensions, e.g. in the main transport direction P and in a vertical direction. In some embodiments, the actuator may be configured for changing a distance between the mask carrier and the substrate carrier in a transverse direction T, perpendicular to the main transport direction P.

In some embodiments, which may be combined with other embodiments described herein, the alignment unit may be fixed to a stationary part of the deposition module above and/or below the plurality of tracks 120, i.e. to a top wall and/or to a bottom wall of the deposition module. In other words, the alignment unit may not be fixed to a side wall of the deposition module, in order to allow for empty carriers to be transported along the return track 123 between the first substrate track 122 and the first side wall 111 of the deposition module. For example, an alignment unit may be fixed to a top wall of the deposition module and protrude at least partially into the space between the first substrate track and the first mask track, and/or an alignment unit may be fixed to a bottom wall of the deposition module and protrude at least partially into the space between the first substrate track and the first mask track.

In some embodiments, one or more alignment units may be arranged in each of the plurality of deposition modules 110, in order to align a substrate carrier with respect to a mask carrier in each deposition module. In some embodiments, an alignment unit may be provided on the first side of the deposition source in each deposition module for aligning a substrate carrier on the first substrate track with respect to a mask carrier on the first mask track, and an alignment unit may be provided on the second side of the deposition source in each deposition module for aligning a substrate carrier on the second substrate track with respect to a mask carrier on the second mask track. The alignment units may be connected to a top wall and/or to a bottom wall of the respective deposition module in some embodiments.

In some embodiments, a mechanical isolation element may be arranged between the actuator of the alignment unit and the chamber wall. The mechanical isolation element may be a vibration damper or an oscillation damper. Accordingly, vibrations, oscillations, or deformations of the chamber walls have a reduced influence or no influence on the alignment of the mask carrier and the substrate carrier. The mechanical isolation element can be configured to compensate for static and/or dynamic deformations.

The alignment unit may include an actuator element for positioning the substrate carrier with respect to the mask carrier. For example, two or more actuators such as piezoelectric actuators for positioning the substrate carrier and the mask carrier with respect to each other may be provided. However, the present disclosure is not limited to piezoelectric actuators. For example, the two or more alignment actuators can be electric or pneumatic actuators. The two or more alignment actuators can for example be linear alignment actuators. In some implementations, the two or more alignment actuators can include an actuator selected from the group consisting of a stepper actuator, a brushless actuator, a DC (direct current) actuator, a voice coil actuator, a piezoelectric actuator, pneumatic actuators, and any combination thereof.

In particular, each deposition module of the plurality of deposition modules may include at least one first alignment unit on the first side of the deposition source for providing an alignment in the first deposition area and at least one second alignment unit on the second side of the deposition source for providing an alignment in the second deposition area.

In some embodiments, which may be combined with other embodiments described herein, the plurality of deposition modules 110 may extend essentially linearly one after the other in the main transport direction P. The transverse direction T may be a horizontal direction essentially perpendicular to the main transport direction P. The substrates and mask device can be transported along the plurality of tracks while being essentially vertically oriented. In other words, the main surface of the substrates and mask devices may be essentially vertical during the transport through the deposition modules. Further, the orientation of the empty carriers on the return track may be essentially vertical.

FIG. 2 is a schematic view of part of a vacuum system 200 including a plurality of deposition modules 110 according to embodiments described herein. The vacuum system 200 includes a first deposition module 201 and a second deposition module 202 arranged downstream from the first deposition module 201 along the main transport direction P. Further deposition modules may be provided. A deposition source 105 is arranged in each of the deposition modules, wherein the deposition sources can move back and forth in the main transport direction P and in a reverse direction R along respective source tracks.

The vacuum system 200 includes a transport system with a plurality of tracks similar to the vacuum system 100 depicted in FIG. 1 so that reference can be made to the above explanations, which are not repeated here. In particular, one or two return tracks for returning empty carriers extend through the deposition modules, particularly adjacent to one or both side walls of the deposition modules. In some embodiments, some tracks or all tracks of the plurality of tracks may be configured for a contactless transport.

In some embodiments, a maintenance area 115 may be provided between the first deposition module 201 and the second deposition module 202 in the main transport direction P. The plurality of tracks 120 may extend through the maintenance area 115 such that substrate carriers and mask carriers are moved through the maintenance area 115, e.g. when a substrate is transported from the first deposition module 201 into the second deposition module 202.

The dimension of the maintenance area 115 may be 50 cm or more, particularly 1 m or more in the main transport direction. The maintenance area 115 may include one or more closable chamber openings in a side wall of the vacuum system where the vacuum system can be opened for accessing a deposition source that is parked in the maintenance area. A deposition source that is parked in the maintenance area 115 for service is schematically indicated with dashed lines in FIG. 2.

The deposition source of the first deposition module 201 and the deposition source of the second deposition module 202 can be transported into the maintenance area 115 along respective source tracks. The maintenance area 115 may be configured for servicing one or more deposition sources which can be moved into the maintenance area 115. For example, the crucible(s) of the deposition sources can be exchanged in the maintenance area 115, the sources may be heated up or cooled down, repaired and/or serviced in the maintenance area 115. One maintenance area may be arranged between two adjacent deposition modules such that the deposition sources of the two adjacent deposition modules can be serviced in one maintenance area. In particular, the source tracks of two adjacent deposition modules may linearly extend into the maintenance area 115 from two opposite sides.

In some embodiments, each deposition source may include a media supply device configured for supplying the deposition source with supply media such as a cooling fluid, electricity, power, control signals, sensor signals and/or further gases or liquids. The media supply devices may be configured as a supply tube or supply channel configured for guiding media supply lines into the respective deposition module. The media supply devices may be fixed to the deposition source such that the media supply devices move together with and in accordance with the deposition sources.

The media supply devices of the deposition sources of two adjacent deposition modules may extend from the deposition sources toward the maintenance area 115, where the media supply devices may be guided out of the vacuum system, e.g. through a respective feed-through in a chamber wall.

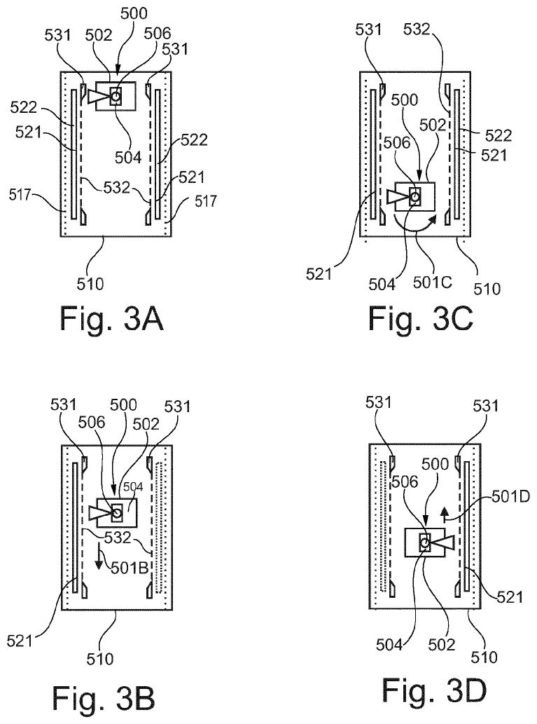

FIGS. 3A to 3D show a deposition source 500 in various positions in a deposition module 510. The deposition module 510 may be one of the plurality of deposition modules 110 of any of the vacuum systems described herein. The movement between the different positions is indicated by arrows 501B, 501C, and 501D. According to embodiments described herein, the deposition source 500 is configured for a translational movement and a rotation around an axis, particularly around an essentially vertical axis. FIGS. 3A to 3D show the deposition source 500 having a crucible 504 and a distribution pipe 506. The distribution pipe 506 is supported by a support 502. Further, according to some embodiments, the crucible 504 can also be supported by the support 502. Two substrates 521 are provided in the deposition module 510 in oppositely arranged deposition areas on a respective substrate track. The substrates 521 are held by a substrate carrier 522 which can be transported along a substrate track, respectively.

Typically, a mask device 532 for masking of the layer deposition on the substrate is provided between the substrate and the deposition source 500 in both deposition areas. As illustrated in FIGS. 3A to 3D, organic material is evaporated from the distribution pipe 506. This is indicated by a triangular plume. The mask devices 532 are held by mask carriers 531 which can be transported along a mask track.

In FIG. 3A, the deposition source 500 is shown in the first position. As shown in FIG. 3B, the left substrate in the deposition module is coated with a layer of organic material by a translational movement of the deposition source 500 as indicated by arrow 501B. While the left substrate 521 is coated with the layer of organic material, a second substrate, e.g. the substrate on the right-hand side in FIGS. 3A to 3D, can be exchanged. After the left substrate 521 has been coated with the layer of organic material, the distribution pipe 506 of the deposition source 500 is rotated as indicated by arrow 501C in FIG. 3C. During deposition of the organic material on the first substrate (the substrate on the left-hand side in FIG. 3B), the second substrate has been positioned and aligned with respect to the mask device via one or more alignment units. The alignment units may be fixed to a stationary part of the deposition module such that empty carriers can be transported along a return track 517 through a space between the substrate track and the side wall of the deposition module. For example, the alignment units may be connected to a top wall and/or to a bottom wall of the deposition module 510 and protrude into a space between the substrate carrier 522 and the mask carrier 531.

Accordingly, after the rotation shown in FIG. 3C, the substrate on the right-hand side, i.e. the second substrate, can be coated with a layer of organic material as indicated by arrow 501D. While the second substrate is coated with the organic material, the first substrate can be moved out of the deposition module into the next deposition module in the main transport direction.

According to embodiments described herein, the substrates are coated with organic material in an essentially vertical orientation. That is, the views shown in FIGS. 3A to 3D are top views of the vacuum system including the deposition source 500. Typically, the distribution pipe is a vapor distribution showerhead, particularly a linear vapor distribution showerhead. The distribution pipe may provide a line source extending essentially vertically.

According to embodiments described herein, which can be combined with other embodiments described herein, essentially vertically is understood particularly when referring to the substrate and mask orientation, to allow for a deviation from the vertical direction of 10° or less. The surface of the substrates is coated by a line source extending in one direction corresponding to one substrate dimension and a translational movement of the evaporation source along the other direction corresponding to the other substrate dimension.

As shown in FIG. 3C, the rotation of the distribution pipe 506, i.e. the rotation from the first substrate to the second substrate, can be about 180°. After the second substrate has been coated as shown in FIG. 3D, the distribution pipe 506 can either be rotated backward by 180° or can be rotated in the same direction as indicated in FIG. 3C. The substrate may be rotated by 360° in total.

According to embodiments described herein, a combination of the translational movement of a line source, e.g. a linear vapor distribution showerhead, and the rotation of the line source, e.g. a linear vapor distribution showerhead, allows for a high evaporation source efficiency and a high material utilization for OLED display manufacturing, wherein a precise masking of the substrate is beneficial. A translational movement of the source allows for a high masking precision since the substrate and the mask can remain stationary. The rotational movement allows for a substrate exchange of one substrate while another substrate is coated with organic material. This significantly improves the material utilization as the idle time, i.e. the time during which the evaporation source evaporates organic material without coating a substrate, is significantly reduced.

In order to achieve good reliability and yield rates, embodiments described herein keep the mask device and substrate stationary during the deposition of organic material. A movable linear source for uniform coating of a large area substrate is provided. The idle time is reduced as compared to an operation wherein after each deposition the substrate needs to be exchanged. Accordingly, having a second substrate in a deposition position and readily aligned with respect to the mask reduces the idle time and increases the material utilization.

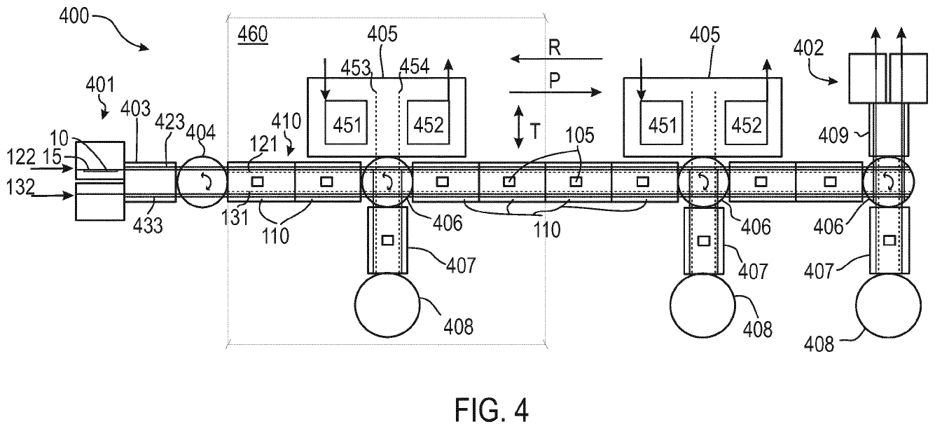

FIG. 4 is a schematic view of a vacuum system 400 for depositing a plurality of materials on a substrate 10 held by a substrate carrier 15 according to embodiments described herein. The vacuum system 400 includes a first substrate handling module 401 configured to attach the substrate 10 to a substrate carrier 15, a second substrate handling module 402 configured to detach the substrate 10 from the substrate carrier 15 after deposition, and a plurality of deposition modules 110 extending in the main transport direction P between the first substrate handling module 401 and the second substrate handling module 402. The plurality of deposition modules 110 house the deposition sources 105 which are movable back and forth in the main transport direction P. The plurality of deposition modules 110 form the main transport path 410 of the vacuum system.

According to embodiments described herein, a transport system is provided including at least one return track 423 extending through the plurality of deposition modules 110 from the second substrate handling module 402 to the first substrate handling module 401. Empty carriers can be transported from the second substrate handling module 402 to the first substrate handling module 401 along the at least one return track 423 through the plurality of deposition modules 110. In some embodiments, two or more return tracks may be provided.

The at least one return track 423 may be configured for a transport of empty carriers in an essentially vertical orientation. The at least one return track 423 may be arranged close to a side wall of the plurality of deposition modules 110 such that the deposition process within the deposition modules is not negatively affected by the returning carriers.

The vacuum system 400 may be configured as an in-line vacuum deposition system, wherein substrates are transported through the plurality of deposition modules 110 along the main transport direction P, and are stopped at predetermined positions in the deposition modules where a material is deposited on the stationary substrates.

The vacuum system 400 may include some of the features or all the features of the vacuum system 100 of FIG. 1, so that reference can be made to the above explanations, which, are not repeated here.

In particular, the vacuum system 400 may include four, eight, twelve or more deposition modules arranged along the main transport path 410 in the main transport direction P. The substrates may be transported through the plurality of deposition modules from the first substrate handling module 401 to the second substrate handling module 402.

A first substrate track and a first mask track may be provided along the main transport path 410 on a first side of the deposition sources 105, and a second substrate track and a second mask track may be provided along the main transport path 410 on a second side of the deposition sources 105. Optionally, return tracks may be provided on both sides of the deposition sources 105, e.g. close to the side walls of the deposition modules. In some embodiments, the plurality of tracks may be parallel to each other. In some embodiments, the transport system may be configured for a contactless transport of the carriers along the plurality of tracks. Particle generation in the deposition modules can be reduced.

A substrate 10 to be coated may be loaded into the vacuum system 400 via a first load lock chamber (not shown in FIG. 4). The substrate 10 may be loaded into the first substrate handling module 401. In the first substrate handling module 401, the substrate 10 may be positioned on a substrate carrier 15 in a first orientation, e.g. in an essentially horizontal orientation (+/−10°). After positioning the substrate 10 on the substrate carrier 15, the substrate carrier may be moved into an essentially vertical orientation, e.g. by a vacuum swing module. The substrate 10 may be held at the substrate carrier 15 by a chucking device, e.g. by an electrostatic chuck.

The first substrate handling module 401 may also be referred to as a “vacuum swing module”, when a vacuum swing station for changing the orientation of the substrate carrier between a horizontal orientation and a vertical orientation is arranged in the first substrate handling module 401. In some embodiments, in the first substrate handling module 401, the substrate carrier 15 which holds the substrate 10 may be positioned on a first substrate track 122 in an essentially vertical orientation.

In some embodiments, the first substrate handling module 401 may include a first vacuum swing station configured for arranging a substrate carrier 15 on a first substrate track 122 and a (optional) second vacuum swing station configured for arranging a further substrate carrier on a second substrate track 132.

In some embodiments, the vacuum system 400 may include a buffer module 403 which is arranged downstream from the first substrate handling module 401, e.g. between the first substrate handling module 401 and the plurality of deposition modules 110. In some embodiments, a track switch device may be provided in the buffer module 403. The track switch device may be configured for translating substrate carriers between the at least one return track 423, a second return track 433, the first substrate track 122, and/or the second substrate track 132 in a transverse direction T, e.g. perpendicular to the main transport direction P. For example, an empty carrier which has returned along the at least one return track 423 may be translated in the transverse direction T onto the first substrate track 122. Alternatively or additionally, the buffer module 403 may include a carrier storage or a carrier parking area for the temporary storage of one, two or more substrate carriers.

In some embodiments, the vacuum system 400 may further include a carrier rotation module 404. The carrier rotation module 404 may be arranged downstream from the first substrate handling module 401 and/or the buffer module 403, and upstream from the plurality of deposition modules 110. The carrier rotation module 404 may be configured for rotating substrate carriers holding a substrate. Accordingly, the orientation of a substrate that is held by a substrate carrier may be reverted in the carrier rotation module 404. Further, a substrate carrier may switch between the first substrate track 122 and the second substrate track 132. The carrier rotation module 404 may include two or more rotatable substrate tracks. In some embodiments, e.g. when only one vacuum swing station is provided in the first substrate handling module 401, the orientation of the substrates which are to be coated along the second substrate track 132 can be changed by rotation in the carrier rotation module. In particular, by reverting the orientation of a substrate held by a substrate carrier, it can be made sure that the main surface of the substrate faces toward the deposition sources 105.

The carrier rotation module 404 is an optional component. For example, instead of providing the carrier rotation module 404, a second vacuum swing station for positioning substrate carriers on the second substrate track 132 in a correct orientation may be provided.

In some embodiments, two or more deposition modules of the plurality of deposition modules 110 may be provided downstream from the first substrate handling module 401. The deposition modules may be arranged directly adjacent to each other along the main transport path 410. Alternatively, a maintenance area may be provided between the deposition modules, similar to the maintenance area 115 depicted in FIG. 2. Substrates held by substrate carriers may be transported through the deposition modules along the first substrate track 122 and along the second substrate track 132 on both sides of the deposition sources 105.

In some embodiments, the vacuum system 400 may include one or more rotation modules 406 configured for rotating a substrate, a mask and/or an empty carrier around a rotation axis.

For example, a rotation module 406 may be arranged between two deposition modules of the plurality of deposition modules 110 in the main transport path. For example, the rotation module 406 may be arranged downstream from a first subset of the plurality of deposition modules 110 and upstream from a second subset of the plurality of deposition modules 110 in the main transportation path 410. The rotation module 406 may include a plurality of rotatable tracks, wherein, in a first rotation position, the plurality of rotatable tracks may extend in the main transport direction P, and, in a second rotation position, the plurality of rotatable tracks may extend in the transverse direction T.

Accordingly, in the first rotation position, substrates, mask devices and/or empty carriers may be transported through the rotation module 406 along the main transportation path 410, e.g. from an upstream deposition module to a downstream deposition module. In the first rotation position, a substrate and/or a mask device may be routed into or out of the main transportation path 410 in the transverse direction T.

For example, the rotation module 406 may be provided for routing mask devices into the main transport path 410 and/or for routing mask devices out of the main transport path 410 in the transverse direction T. In particular, mask devices to be used may be routed from a mask handling module 405 via the rotation module 406 into the main transport path where the mask devices to be used may be positioned in one of the deposition modules, respectively. Used mask devices may be routed from the main transport path via the rotation module 406 back into the mask handling module 405, e.g. to be unloaded from the vacuum system.

The rotation module 406 may include a plurality of rotatable tracks, e.g. a first mask track and a first substrate track arranged on a first side of the rotation axis, and a second mask track and a second substrate track arranged on a second side of the rotation axis opposite to the first side. In some embodiments, the rotation module 406 may include at least one rotatable return track for returning empty carriers toward the first substrate handling module 401. In some embodiments, the rotation module 406 may include six rotatable tracks, e.g. three rotatable tracks on each side of the rotation axis.

In some embodiments, which may be combined with other embodiments described herein, the vacuum system 400 may include a mask handling module configured for handling mask devices. The mask handling module 405 may include a mask handling assembly for attaching mask devices to mask carriers and/or for detaching mask devices from mask carriers. For example, a first mask handling assembly 451 for attaching mask devices to mask carriers may be provided in the mask handling module 405, and a second mask handling assembly 452 for detaching mask devices from mask carriers may be provided in the mask handling module 405.

The first mask handling assembly 451 may be configured for loading a mask device into the vacuum system 400 in a non-horizontal orientation, e.g. via a load lock chamber, for rotating the mask device into an essentially vertical orientation, and for attaching the mask device to a mask carrier which may be provided on a first mask side track 453 in an essentially vertical orientation. The mask carrier may then be transported along the first mask side track 453 in the transverse direction T into a rotation module 406 and may be routed into the main transport path 410. The mask carrier may then be transported along the main transport path 410 into one of the deposition modules along the first mask track or along the second mask track.

The second mask handling assembly 452 may be configured for detaching a mask device from a mask carrier that may be arranged on a second mask side track 454 in the mask handling module 405. The detached mask device may be rotated from an essentially vertical orientation into a non-vertical orientation and may be unloaded from the vacuum system 400, e.g. via a load lock chamber.

The first mask handling assembly 451 and/or the second mask handling assembly 452 may include a robot device, e.g. a robot arm, configured for a rotational movement and for a translational movement of a mask holding portion. Further, the robot device may include a chucking device such as a magnetic chuck for attracting the mask device to the mask holding portion of the robot device. In some embodiments, the robot device may be configured for initiating an attachment or a detachment of a mask device from a mask carrier, e.g. by controlling a magnetic chuck that may be provided for holding the mask device at a holding surface of the mask carrier.

In some embodiments, each mask handling module 405 may be configured to supply mask devices to a number of associated deposition modules of the plurality of deposition modules. For example, the vacuum system 400 of FIG. 4 includes two mask handling modules 405 and eight deposition modules arranged along the main transportation path 410, wherein four deposition modules may be associated to each mask handling module 405. A mask handling module 405 may supply the associated deposition sources with clean mask devices and may unload used mask devices from the associated deposition sources from the vacuum system, e.g. for cleaning or maintenance. For example, the mask handling module 405 on the left side in FIG. 4 may be associated to the upstream deposition modules, and the mask handling module on the right side in FIG. 4 may be associated to the downstream deposition modules.

The mask handling modules 405 may be arranged sideward with respect to the main transportation path 410 such that mask carriers carrying mask devices to be used can be routed into the main transportation path 410 from the mask handling module 405 via a rotation module 406, and mask carriers carrying used mask devices can be routed out of the main transportation path into the mask handling module 405 via a rotation module 406. A space-saving and compact vacuum system can be provided. Further, the cycle tact of the system can be decreased, since the time for a mask exchange in the deposition modules can be decreased by providing two or more mask handling modules for supplying respective sections of the main transport path 410. In some embodiments, two or more mask devices of adjacent deposition modules may be exchanged at the same time.

In some embodiments, one mask handling module 405 and the associated deposition modules that are supplied with mask devices by the mask handling module 405 form one “cluster” of the vacuum system. An exemplary cluster 460 is framed with a dashed square in FIG. 4. Each cluster may include a portion of the main transport path 410 including a subset of the plurality of deposition modules 110, a rotation module 406 arranged in the main transportation path 410, e.g. between two deposition modules of the subset, and a mask handling module 405 arranged adjacent to the rotation module 406, wherein the rotation module may be configured for routing mask devices into and out of the main transportation path 410. Optionally, the cluster may further include one or more side deposition modules 407 extending in a transverse direction T with respect to the main transport direction P. The rotation module 406 may be configured for routing substrates and mask devices into the side deposition module 407 from the main transportation path 410. Side substrate tracks and side mask tracks may be provided in the side deposition module 407.

A side deposition module 407 may be understood as a deposition module arranged adjacent to a rotation module 406 on a side of the main transportation path 410 and including one or more side tracks extending in a transverse direction T with respect to the main transport direction P. A deposition source may be provided in each side deposition module. For example, a side deposition module 407 may be used as an additional deposition chamber configured for increasing the thickness of a previously deposited material layer.

In some embodiments, which may be combined with other embodiments described herein, a maintenance module 408 may optionally be arranged adjacent to a deposition module, particularly adjacent to a side deposition module 407 at a side facing away from the main transportation path 410. Source tracks for transporting the deposition source of the deposition module into the maintenance module 408 may extend between the maintenance module 408 and the side deposition module 407. The deposition source may be moved into the maintenance module 408 for service or maintenance or during idle times of the system.

In some embodiments, which may be combined with other embodiments described herein, a track switch module may be provided. A track switch assembly configured to translate a carrier between two or more tracks of the plurality of tracks in a transverse direction T may be provided in the track switch module. For example, the buffer module 403 of FIG. 4 may be configured as a track switch module.

In some embodiments, one or more substrate handling modules configured to attach the substrate to a substrate carrier or to detach the substrate from the substrate carrier may be provided. For example, the first substrate handling module 401 may be arranged at an upstream end of the vacuum system, wherein the first substrate handling module 401 may include a substrate handling assembly for attaching a substrate to a substrate carrier. For example, the second substrate handling module 402 may be arranged at a downstream end of the vacuum system, wherein the second substrate handling module 402 may include a substrate handling assembly for detaching a substrate from a substrate carrier.

In some embodiments, a second buffer module 409 may be arranged downstream from the plurality of deposition modules 110. As is exemplarily depicted in FIG. 4, the second buffer module 409 may extend in the transverse direction T, and a rotation module 406 may be provided adjacent to the second buffer module 409 for changing the orientation of the substrate carriers. As will be apparent, in alternative embodiments, the second buffer module 409 may extend in the main transport direction P.

In some embodiments, a first plurality of deposition modules may be arranged one after the other in the main transport direction, and a second plurality of deposition modules may be arranged one after the other in a transverse direction. A rotation module may connect the first plurality of deposition modules and the second plurality of deposition modules.

In some embodiments, a second substrate handling module 402 may be arranged at a downstream end of the vacuum system 400. Coated substrates may be detached from the substrate carriers in the second substrate handling module 402 and unloaded from the vacuum system 400. As is schematically depicted in FIG. 4, the second substrate handling module may include two vacuum swing stations, wherein a first vacuum swing station may be configured for detaching substrates from substrate carriers on the first substrate track 122, and a second vacuum swing station may be configured for detaching substrates from substrate carriers on the second substrate track 132. Alternatively or additionally, it may also be possible to change the orientation of the substrate carrier in the most downstream rotation module so that a single vacuum swing station may be sufficient in some embodiments.

The empty substrate carriers are transported along the at least one return track 423 and/or along a second return track 433 from the second substrate handling module 402 through the plurality of deposition modules back to the first substrate handling module 401 where a new substrate to be coated can be attached to the empty substrate carrier.

As already explained in more detail above, alignment units for aligning a substrate carrier with respect to a mask carrier may be provided in each of the deposition modules.

According to a further aspect of the present disclosure, a method of depositing a plurality of materials on a substrate is described. The method includes transporting a substrate carrier holding a substrate along a first substrate track in a main transport direction P through a plurality of deposition modules.

The substrate is stopped at a predetermined position in a deposition module, and a material is deposited on the substrate with a deposition source. Therein, the deposition source is moved past the substrate. The deposition source may be an evaporation source which is configured for a translation in the main transport direction P.

The transport of the substrate carrier which holds the substrate may continue in the main transport direction P, until the substrate is arranged in a subsequent deposition module. The substrate is stopped at a predetermined position in the subsequent deposition module, and a further material is deposited on the substrate with a further movable deposition source.

After the transport of the substrate through the plurality of deposition modules, a stack of layers may be formed on the substrate.

The substrate may be detached from the substrate carrier in a second substrate handling module provided at downstream end of the vacuum system, and the empty carrier may be transported along a return track through the plurality of deposition modules in a return direction opposite to the main transport direction. The return track may be arranged between a substrate track and a side wall of the plurality of vacuum modules.

Thereafter, a new substrate to be coated may be attached to the empty carrier in a first substrate handling module.

In some embodiments, the method may further include: transporting a mask carrier holding a mask device along a first mask track, and aligning the substrate carrier with respect to the mask carrier with an alignment unit provided in one of the deposition modules.

The mask track may extend parallel to the substrate track through the plurality of deposition modules. The alignment unit may be connected to a top wall and/or to a bottom wall of the deposition module.

The term “carrier” as used herein may refer to a substrate carrier configured for carrying a substrate through the vacuum system or to a mask carrier configured for carrying a mask device through the vacuum system. A mask carrier is configured to carry a mask device during processing, i.e. during transport in the vacuum system and/or during deposition. In some embodiments, the mask device may be held at the mask carrier in an essentially vertical orientation.

A carrier may include a carrier body with a holding surface configured to carry a substrate or a mask device, particularly in an essentially vertical orientation. For example, a substrate may be attached to a substrate carrier by a chucking device, e.g. by an electrostatic chuck and/or by a magnetic chuck. For example, a mask device may be attached to a mask carrier by a chucking device, e.g. an electrostatic chuck and/or a magnetic chuck. Other types of chucking devices may be used.

“Transporting”, “moving”, or “routing” of substrates or mask devices as used herein typically refers to a respective movement of a carrier which holds the substrate or the mask device at a holding surface of the carrier, particularly in an essentially vertical orientation.

While the foregoing is directed to embodiments of the disclosure, other and further embodiments of the disclosure may be devised without departing from the basic scope thereof, and the scope thereof is determined by the claims that follow.

1. A vacuum system for depositing a plurality of materials on a substrate, comprising:
a plurality of deposition modules arranged along a main transport direction and comprising deposition sources which are movable in the main transport direction; and
a transport system with a plurality of tracks extending in the main transport direction through the plurality of deposition modules and comprising a first mask track for mask transport, a first substrate track for substrate transport and a return track for returning empty carriers.

2. The vacuum system of claim 1, wherein the first mask track, the first substrate track, and the return track extend parallel to each other on a first side of the deposition sources.

3. The vacuum system of claim 1, wherein the plurality of tracks further comprises a second mask track for mask transport, a second substrate track for substrate transport, and a second return track for returning empty carriers.

4. The vacuum system of claim 3, wherein the second mask track, the second substrate track, and the second return track extend parallel to each other on a second side of the deposition sources.

5. The vacuum system of claim 1, wherein the plurality of tracks is configured for transporting substrate carriers or mask carriers in an essentially vertical orientation.

6. The vacuum system of claim 1, wherein the transport system is configured for a contactless transport of substrate carriers and mask carriers.

7. The vacuum system of claim 1, wherein the deposition sources are rotatable around a respective rotation axis.

8. The vacuum system of claim 1, wherein the deposition sources are evaporation sources configured for depositing organic materials on the substrate and comprise a crucible and a distribution pipe extending in an essentially vertical direction and having a plurality of vapor openings.

9. The vacuum system of claim 1, further comprising an alignment unit configured for aligning a substrate carrier on the first substrate track with respect to a mask carrier on the first mask track.

10. The vacuum system of claim 9, wherein the alignment unit is connected to a wall of a deposition module, and comprises a first mount for mounting a substrate carrier to the alignment unit and a second mount for mounting a mask carrier to the alignment unit.

11. The vacuum system of claim 1, further comprising:
a rotation module arranged between two deposition modules of the plurality of deposition modules and comprising a plurality of rotatable tracks, wherein, in a first rotation position, the plurality of rotatable tracks extends in the main transport direction, and, in a second rotation position, the plurality of rotatable tracks extends in a transverse direction.

12. The vacuum system of claim 1, further comprising one or more of:
a mask handling module comprising a mask handling assembly for attaching mask devices to mask carriers and/or for detaching mask devices from mask carriers;
a side deposition module arranged adjacent to a rotation module and comprising one or more side tracks extending in a transverse direction with respect to the main transport direction;
a maintenance module arranged adjacent to a side deposition module, wherein source tracks for transporting a deposition source extend between the maintenance module and the side deposition module;
a track switch module comprising a track switch assembly configured to translate a carrier between two or more tracks of the plurality of tracks in a transverse direction; and
one or more substrate handling modules configured to attach the substrate to a substrate carrier or to detach the substrate from the substrate carrier.

13. A vacuum system for depositing a plurality of materials on a substrate held by a substrate carrier, comprising:
a first substrate handling module configured to attach a substrate to a substrate carrier;
a second substrate handling module configured to detach the substrate from the substrate carrier;
a plurality of deposition modules arranged along a main transport direction between the first substrate handling module and the second substrate handling module and comprising deposition sources which are movable in the main transport direction; and
at least one return track extending through the plurality of deposition modules from the second substrate handling module to the first substrate handling module.

14. A method of depositing a plurality of materials on a substrate, comprising:
transporting a substrate carrier holding a substrate along a first substrate track in a main transport direction through a plurality of deposition modules;
depositing a plurality of materials on the substrate in the plurality of deposition modules with deposition sources which are movable in the main transport direction; and
transporting an empty carrier along a return track through the plurality of deposition modules in a return direction opposite to the main transport direction.

15. The method of claim 14, further comprising:
transporting a mask carrier holding a mask device along a first mask track parallel to the first substrate track; and
aligning the substrate carrier with respect to the mask carrier with an alignment unit provided in one of the deposition modules.

16. The vacuum system of claim 2, wherein the return track is arranged between the first substrate track and a first side wall of the plurality of deposition modules.

17. The vacuum system of claim 6, wherein the transport system comprises a plurality of magnetic levitation devices.

18. The vacuum system of claim 1, wherein the deposition sources are linearly movable along source tracks extending in the main transport direction.

19. The vacuum system of claim 10, wherein the alignment unit is connected to at least one of a top wall and a bottom wall of the deposition module.

20. The method of claim 15, wherein the alignment unit is connected to at least one of a top wall and a bottom wall of the deposition module.
